(19) United States
(12) Patent Application Publication
(10) Pub. No.: US 2014/0285787 A1
(43) Pub. Date: Sep. 25, 2014

(54) EXPOSURE SYSTEM AND EXPOSURE METHOD

(71) Applicant: Kabushiki Kaisha Toshiba, Minato-ku (JP)

(72) Inventors: Eiji YONEDA, Mie-ken (JP); Nobuhiro Komine, Aichi-ken (JP); Satomi Higashibata, Mie-ken (JP); Kazutaka Ishigo, Mie-ken (JP); Yosuke Okamoto, Tokyo (JP)

(73) Assignee: Kabushiki Kaisha Toshiba, Minato-ku (JP)

(21) Appl. No.: 14/013,183

(22) Filed: Aug. 29, 2013

(30) Foreign Application Priority Data
Mar. 21, 2013 (JP) 2013-059138

(51) Int. Cl. G03F 7/20

(52) U.S. Cl. CPC G03F 7/70191
USPC 355/71

(57) ABSTRACT

According to one embodiment, an exposure system includes: a supporting stage; a plurality of masks provided on an upper side of the supporting stage; and a light source being capable of irradiating a substrate with light through the plurality of masks, the plurality of masks including: a first mask, and a light shielding film being patterned in the first mask; and a second mask provided on an upper side or a lower side of the first mask, the second mask including a second region facing a first region of the first mask, the light shielding film not being present in the first region, and a light shielding film not being patterned in the second region or the light shielding film being patterned in at least a part of the second region, and a plurality of laser-irradiated marks being provided in at least the second region of the second mask.

### CROSS-REFERENCE TO RELATED APPLICATIONS

This application is based upon and claims the benefit of priority from Japanese Patent Application No. 2013-059138, filed on Mar. 21, 2013; the entire contents of which are incorporated herein by reference.

### FIELD

Embodiments described herein relate generally to an exposure system and an exposure method.

### BACKGROUND

A photolithography technology generally employs an exposure system. An optical system of the exposure system is configured by: a light source provided for exposure; an illumination optical system which turns light supplied from the light source into desired illumination light; a mask in which a light shielding film is patterned in order to supply pattern information onto a wafer; a projection lens which reduces the pattern information; and a stage which holds and moves the wafer. The light having transmitted through the mask passes through the projection lens, for example, and forms an image on a substrate such as a semiconductor wafer.

However, as the pattern formed on the substrate becomes finer, dimensional variation and misalignment of the pattern formed on the substrate have become a problem. In particular, a nonlinear component of the mask based on a strain component or the like of the mask has become a problem with regard to the misalignment.

### BRIEF DESCRIPTION OF THE DRAWINGS

FIG. 1 is a schematic cross-sectional view showing an exposure system according to an embodiment;

FIG. 2A is a schematic cross-sectional view schematically showing a part of the mask in the exposure system according to the embodiment, and FIG. 2B is a schematic view showing the control unit in the exposure system according to the embodiment;

FIG. 3 is a schematic cross-sectional view showing the exposure system according to a reference example;

FIG. 4A is a diagram showing the dimensional variation within a shot, and FIG. 4B is a diagram showing the misalignment of the nonlinear component by a mask;

FIG. 5 is a schematic cross-sectional view showing an example of a mask in the exposure system according to the reference example;

FIG. 6A is a diagram showing a state after the dimensional variation within a shot has been corrected, FIG. 6B is a diagram showing how the misalignment of the nonlinear component by a mask is corrected, and FIG. 6C is a diagram showing a state after the misalignment of the nonlinear component by a mask has been corrected; and

FIG. 7 is a flow chart showing an exposure method according to the embodiment.

### DETAILED DESCRIPTION

In general, according to one embodiment, an exposure system includes: a supporting stage supporting a substrate; a plurality of masks provided on an upper side of the supporting stage; and a light source being capable of irradiating the substrate with light through the plurality of masks, the plurality of masks including: a first mask, and a light shielding film being patterned in the first mask; and a second mask provided on an upper side or a lower side of the first mask, the second mask including a second region facing a first region of the first mask, the light shielding film not being present in the first region, and a light shielding film not being patterned in the second region or the light shielding film being patterned in at least a part of the second region, and a plurality of laser-irradiated marks being provided in at least the second region of the second mask.

Embodiments will be described below with reference to the drawings. In the description below, the same member will be assigned the same reference numeral so that the description of a member described once will be omitted as appropriate.

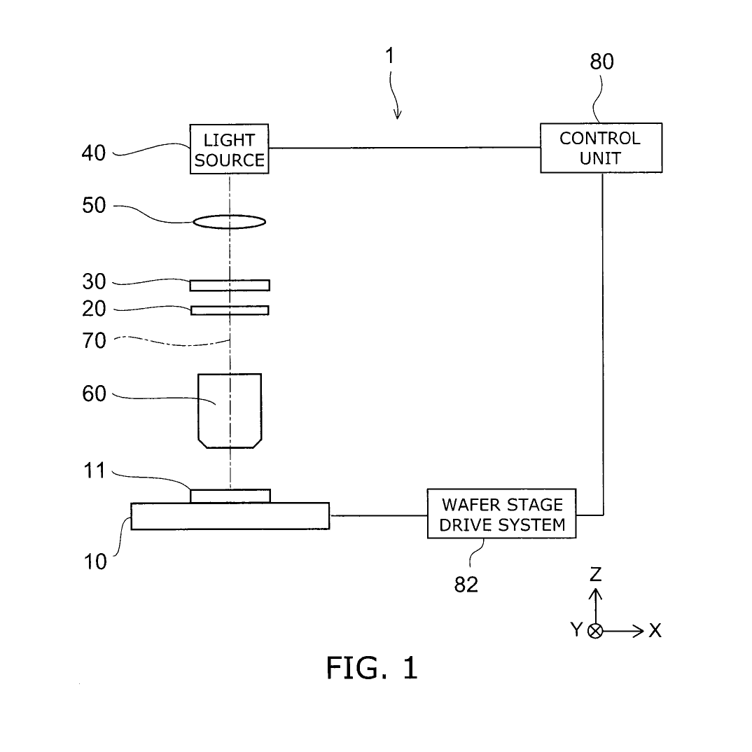

FIG. 1 is a schematic cross-sectional view showing an exposure system according to the embodiment.

As shown in FIG. 1, an exposure system 1 according to the embodiment includes a supporting stage 10, a plurality of masks (such as a first mask 20 and a second mask 30), and a light source 40. The exposure system 1 further includes an illumination optical system (such as a condenser lens) 50, a projection lens 60, and a control unit 80.

The exposure system 1 of the embodiment includes: the light source 40 provided for exposure; the illumination optical system 50 which turns light 70 supplied from the light source 40 into desired illumination light; the plurality of masks 20 and 30 provided between the illumination optical system 50 and the projection lens 60; the projection lens 60 which reduces pattern information; and the supporting stage 10 which supports and moves a substrate 11.

The plurality of masks 20, 30 correspond to a first mask 20 in which a light shielding film is patterned and at least one of second masks 30 provided in the vicinity and on an optical axis of the first mask 20 to control transmittance of exposure light. A plurality of laser-irradiated marks is provided in a second region of the second mask 30, the second region facing a first region of the first mask where the light shielding film is not patterned in the first region.

The substrate 11 is supported by the supporting stage 10. The movement of the supporting stage 10 is controlled by a wafer stage drive system 82 connected to the control unit 80. The substrate 11 is a semiconductor wafer or the like. The first mask 20 can be supported and moved by a supporting stage not shown. The first mask 20 is provided on an upper side of the supporting stage 10. The first mask 20 is a photomask (reticle) used in a photolithography process.

The second mask 30 is provided on an upper side of the first mask 20 as an example, but may be provided on a lower side of the first mask 20 instead. The light source 40 can irradiate the substrate 11 with the light 70 through the plurality of masks (such as the second mask 30 and the first mask 20). The light 70 is ArF light, KrF light, or an i-ray, for example, where the wavelength of the light 70 is 100 nm to 400 nm.

In the exposure system 1, the light 70 emitted from the light source 40 is turned into desired illumination by the illumination optical system 50 and then supplied to the second mask 30. The light 70 having transmitted through the second mask 30 is supplied to the projection lens 60 through the first mask 20. The patterned light shielding film is formed in the first mask 20, and thus the light 70 not shielded by the light shielding film reaches the projection lens 60. The light 70 having passed through the projection lens 60 forms an image on a surface of the substrate 11. The first mask 20 has a role of conveying the pattern information.

The second mask 30 can be scanned on an upper side of the substrate 11 in synchronization with the first mask 20. For example, a unit including the first mask 20 and the second mask 30 in the exposure system 1 can serve as a pair during exposure and be scanned in a direction indicated by an arrow in FIG. 1 (an X direction or a Y direction). Working together with the unit, the supporting stage 10 can be scanned in the X direction and the Y direction. The scanning is automatically controlled by the control unit 80.

The light source 40 need not be disposed above the illumination optical system 50. That is, the light 70 emitted from the light source 40 may appropriately be supplied into the illumination optical system 50 by use of an optical system unit (not shown) or the like.

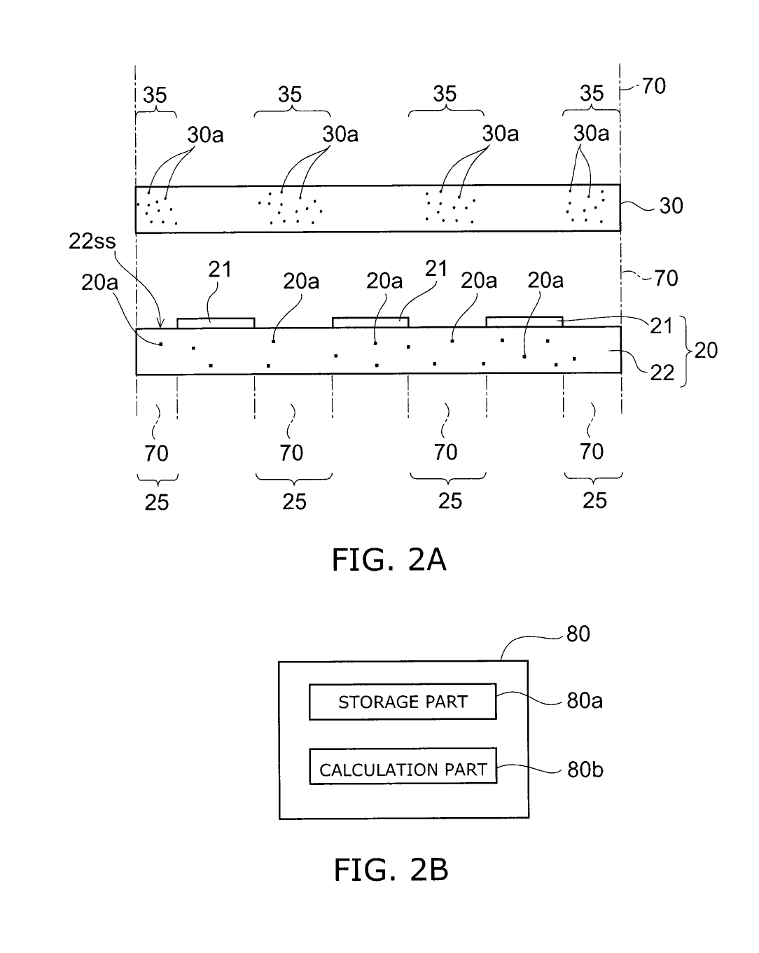

FIG. 2A is a schematic cross-sectional view schematically showing a part of the mask in the exposure system according to the embodiment, whereas FIG. 2B is a schematic view showing the control unit in the exposure system according to the embodiment.

A light shielding film 21 is patterned on a surface 22ss of a light transparent substrate 22 of the first mask 20 shown in FIG. 2A. The light shielding film 21 includes metal such as chromium (Cr). There is also a case where a plurality of laser-irradiated marks 20a is provided in the light transparent substrate 22 of the first mask 20.

The light shielding film 21 being provided in the first mask 20, the light 70 selectively transmits through a region 25 of the first mask 20 where the light shielding film 21 is not provided. The light 70 having selectively transmitted reaches the substrate 11 through the projection lens 60. The composition of the light transparent substrate 22 of the first mask 20 includes quartz or glass, for example. Moreover, the first mask 20 may be a phase shift mask instead.

The light shielding film 21 is not patterned in a second region 35 of the second mask 30 or in an almost whole area thereof shown in FIG. 2A. That is, the light shielding film 21 is not patterned in at least the second region 35. The second region 35 faces the first region 25 of the first mask 20 where the light shielding film 21 is not patterned. The second mask 30 is a light transparent substrate. The composition of the second mask 30 includes quartz, glass, or the like. There is also a case where a plurality of laser-irradiated marks 30a is provided in at least the second region 35 of the second mask 30. The laser-irradiated mark 30a may be provided not only in the second region 35 but also in the whole area of the second mask 30. Alternatively, the laser-irradiated mark 30a may be provided in a part of the second mask 30.

Moreover, the second mask 30 is provided with an alignment mark required to align the mask and a reference mark which specifies a coordinate.

Although not present in most part of the region including the second region 35 of the second mask 30, the light shielding film 21 may be present to the extent that light energy required for patterning a wafer can be supplied. This means that the light shielding film 21 may not be patterned in the second region 35 or may be patterned in at least a part thereof.

The laser-irradiated mark 20a is formed by destructing the crystallinity of quartz when the light transparent substrate 22 is composed of quartz, for example. On the other hand, the laser-irradiated mark 20a is formed by increasing the crystallinity of glass or a crystal or destructing the crystallinity thereof when the light transparent substrate 22 is composed of glass. Alternatively, the laser-irradiated mark 20a may be a crack formed by changing the density of a base material configuring the light transparent substrate 22.

The laser-irradiated mark 30a is formed by destructing the crystallinity of quartz when the second mask 30 is composed of quartz. On the other hand, the laser-irradiated mark 30a is formed by increasing the crystallinity of glass or a crystal or destructing the crystallinity thereof when the second mask 30 is composed of glass. Alternatively, the laser-irradiated mark 30a may be a crack formed by changing the density of a base material configuring the second mask 30.

That is, the structure or physical property (such as a linear expansion coefficient) of the light transparent substrate 22 differs within the same transmitting region (the first region 25) depending on the presence of the laser-irradiated mark 20a. The difference in structure further includes the difference in the linear expansion coefficient, crystalline structure, the density, a refractive index, a stoichiometric ratio, and the like. The laser-irradiated mark 20a is formed at a desired location by irradiation with a femtosecond laser beam, for example.

Moreover, the structure or the physical property (such as transmittance) of the second mask 30 differs depending on the presence of the laser-irradiated mark 30a. The difference in structure further includes the difference in the linear expansion coefficient, the crystalline structure, the density, the refractive index, the stoichiometric ratio, and the like. The laser-irradiated mark 30a is formed at a desired location by irradiation with the femtosecond laser beam, for example.

The femtosecond laser can oscillate by compressing high energy in a short period of time. The structure, the physical property and the like of the light transparent substrate change at a focal point and in the vicinity thereof of the laser beam after the light transparent substrate has been irradiated with the femtosecond laser beam. For example the phase, the density, and the refractive index change at the focal point and in the vicinity thereof of the laser beam.

As described above, the plurality of masks including the laser-irradiated mark is provided in a direction perpendicular to the optical axis of exposure (a Z direction) between the illumination optical system 50 and the projection lens 60 in the exposure system 1.

The control unit 80 shown in FIG. 2B includes a storage part 80a which stores data used for control or the like and a calculation part 80b which calculates and determines the data or the like, for example. Here, the laser-irradiated mark may also be referred to as a pixel mark.

The action of an exposure system according to a reference example will be described before describing the effects of the embodiment. The exposure system according to the reference example as well as an embodiment employing the exposure system according to the reference example are also included in the embodiment.

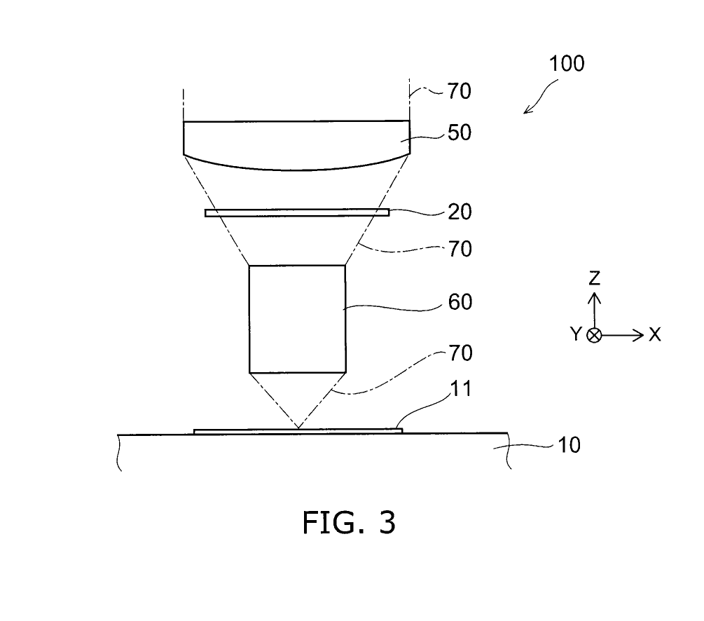

FIG. 3 is a schematic cross-sectional view showing the exposure system according to a reference example.

A light source 40 is omitted from an exposure system 100 shown in FIG. 3. The configuration of the exposure system 100 according to the reference example is the same as that of the exposure system 1 except for the second mask 30 that is not provided in the exposure system 100. At this stage, it is assumed that the aforementioned laser-irradiated mark 20a is not formed in a first mask 20 of the exposure system 100.

As a pattern (such as a circuit pattern) formed on a surface of a substrate 11 becomes finer, the influence of dimensional variation within a shot, and the influence of misalignment of a nonlinear component by the first mask 20 become more conspicuous in exposure. The shot corresponds to a region on the substrate 11 being irradiated with light through a mask.

The dimensional variation within a shot occurs when transmittance of the first mask 20 slightly deviates from target transmittance, for example. That is, the pattern formed on the substrate 11 varies when the amount of light transmitting through the first mask 20 deviates from a target value. For example, the line width of a resist pattern varies due to the deviation in adjusting the amount of light.

Moreover, the misalignment of the nonlinear component by the first mask 20 indicates a component that cannot be corrected by an expose device because of strain or deflection in the first mask 20, for example.

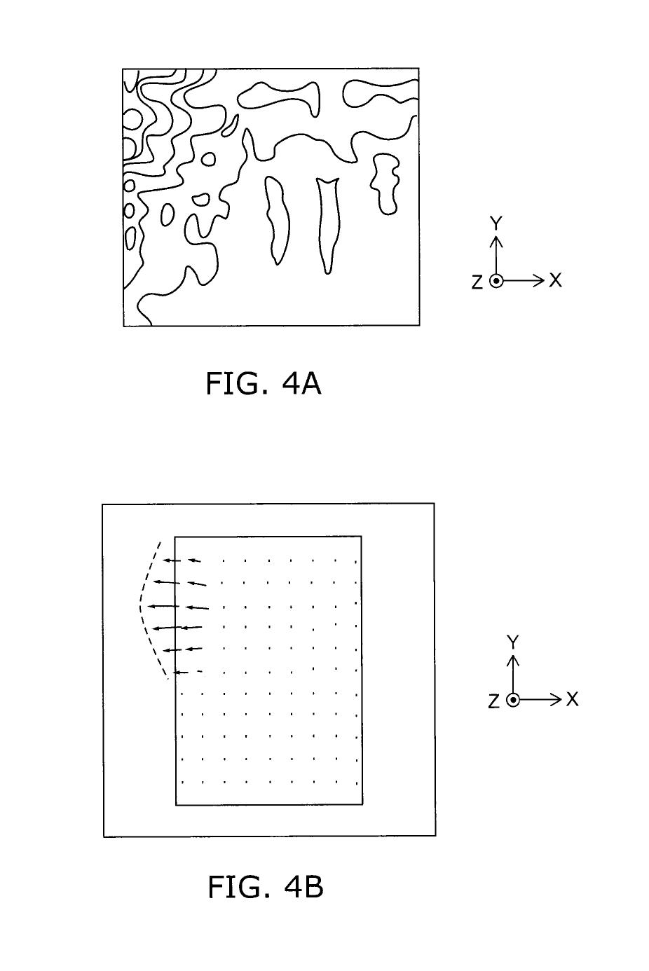

FIG. 4A is a diagram showing the dimensional variation within a shot, whereas FIG. 4B is a diagram showing the misalignment of the nonlinear component by a mask.

In-plane distribution of the dimensional variation within a shot per shot is schematically shown by a contour line in FIG. 4A. FIG. 4A indicates that the sparser the interval of the contour line, the smaller the dimensional variation. It can be understood from a portion where the interval of the contour line is dense, in FIG. 4A, that the dimensional variation is generated in the exposure system 100.

On the other hand, the misalignment of the nonlinear component by a mask is shown by a vector in FIG. 4B. The shorter the length of the vector and the more aligned each vector is in the same direction (such as the X direction or the Y direction), the smaller the misalignment of the nonlinear component. However, it can be understood from FIG. 4B that the misalignment of the nonlinear component is locally present in the exposure system 100.

The reference example implements a measure as follows in order to suppress the dimensional variation within a shot and the misalignment of the nonlinear component.

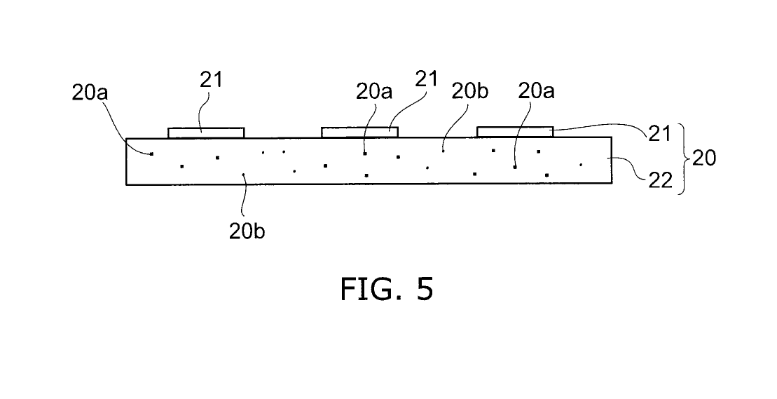

FIG. 5 is a schematic cross-sectional view showing an example of a mask in the exposure system according to the reference example.

For example, the dimensional variation within a shot is suppressed by forming a plurality of laser-irradiated marks 20b in the light transparent substrate 22. That is, light transmittance of the first mask 20 is adjusted to a desired value by varying the crystallinity of the light transparent substrate 22 here and there inside the light transparent substrate 22.

Moreover, the misalignment is suppressed by forming the plurality of laser-irradiated marks 20a in the light transparent substrate 22. The local nonlinear component by the first mask 20 is corrected by forming the plurality of laser-irradiated marks 20a in the light transparent substrate 22.

For example, an expansion/contraction ratio of the light transparent substrate 22 is locally adjusted by forming the plurality of laser-irradiated marks 20a in the light transparent substrate 22. Accordingly, the misalignment of the local nonlinear component by the first mask 20 is corrected.

Misalignment of a linear component can be easily corrected by adjusting the scaling of the length and the width of a shot. However, the correction of the misalignment of the nonlinear component is difficult as compared to the correction of the misalignment of the linear component. Thus, the plurality of laser-irradiated marks 20a is formed in the light transparent substrate 22 to correct the misalignment of the nonlinear component.

Moreover, the plurality of laser-irradiated marks 20a and 20b are formed by irradiating the light transparent substrate 22 with the femtosecond laser beam as described above.

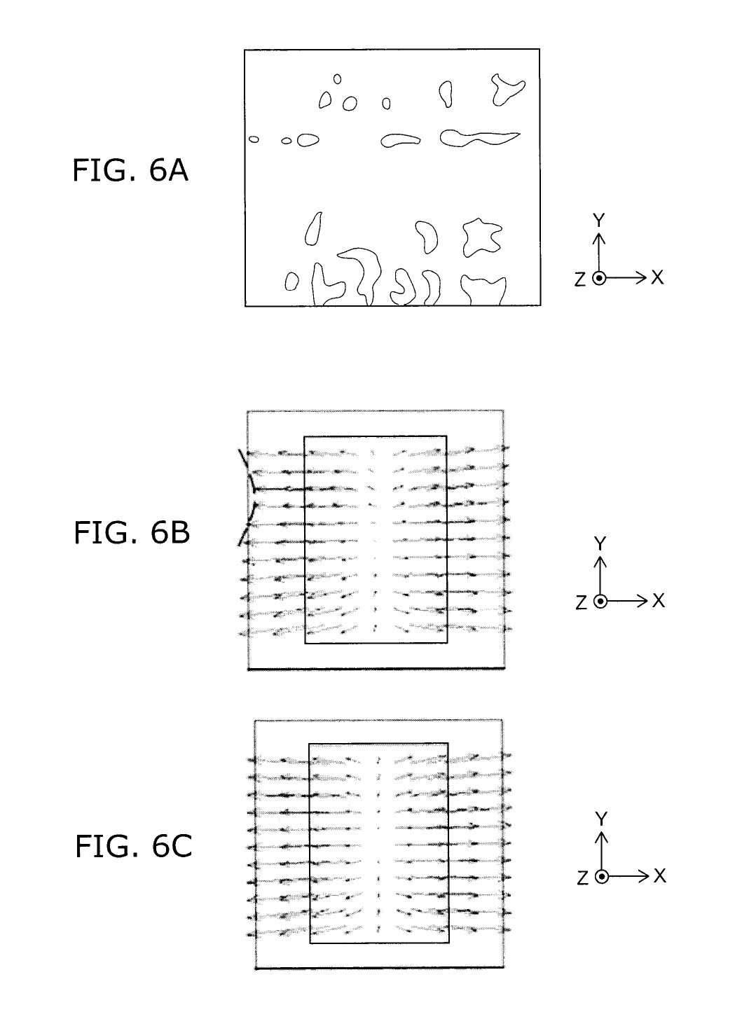

FIG. 6A is a diagram showing a state after the dimensional variation within a shot has been corrected, FIG. 6B is a diagram showing how the misalignment of the nonlinear component by a mask is corrected, and FIG. 6C is a diagram showing a state after the misalignment of the nonlinear component by a mask has been corrected.

In-plane distribution of the dimensional variation within a shot per shot is schematically shown by a contour line in FIG. 6A. As shown in FIG. 6A, it is understood that the dimensional variation within a shot has decreased after correction as compared to FIG. 4A. Moreover, the misalignment is corrected as shown in FIG. 6B on the basis of the misalignment in FIG. 4B. As a result, it is understood that the nonlinear component has decreased as shown in FIG. 6C, whereby the misalignment is aligned in the X direction and is now linear. From here on the optical correction can easily be made by adjusting the scaling of the length and the width of the shot.

However, the laser-irradiated mark 20b and the laser-irradiated mark 20a are formed in the same light transparent substrate 22 in the reference example. This means that the correction of the dimensional variation within a shot and the correction of the misalignment of the nonlinear component by a mask may interfere with each other. This interference becomes more conspicuous as a pattern becomes finer.

For example, the laser-irradiated mark 20a has already been formed in the light transparent substrate 22 at the time of forming the laser-irradiated mark 20b, when the dimensional variation within a shot is corrected after correcting the misalignment of the nonlinear component by a mask. When the crystallinity and size of the laser-irradiated mark 20b resemble the crystallinity and size of the laser-irradiated mark 20a, the laser-irradiated mark provided for adjusting the alignment and the laser-irradiated mark provided for adjusting the illuminance interfere with each other, whereby the alignment adjustment and the illuminance adjustment cannot be controlled as intended. This is because the laser-irradiated mark 20b is used not only for correcting the illuminance but also for correcting the alignment. That is, the correction work also causes the shift in the reference example.

For example, the laser-irradiated mark 20a has already been formed in the light transparent substrate 22 at the time of forming the laser-irradiated mark 20b, when the dimensional variation within a shot is corrected after correcting the misalignment of the nonlinear component by a mask.

When the position, crystallinity and size of the laser-irradiated mark 20b are contiguous to/resemble the position, crystallinity and size of the laser-irradiated mark 20a, the laser-irradiated mark provided for adjusting the alignment and the laser-irradiated mark provided for adjusting the illuminance interfere with each other, whereby the alignment adjustment and the illuminance adjustment cannot be controlled as intended. This is because the laser-irradiated mark 20b is used not only for correcting the illuminance but also for correcting the alignment. That is, the correction work also causes the shift in the reference example.

In contrast, the exposure system 1 of the embodiment includes the first mask 20 and the second mask 30 as the mask and performs the correction in an order below.

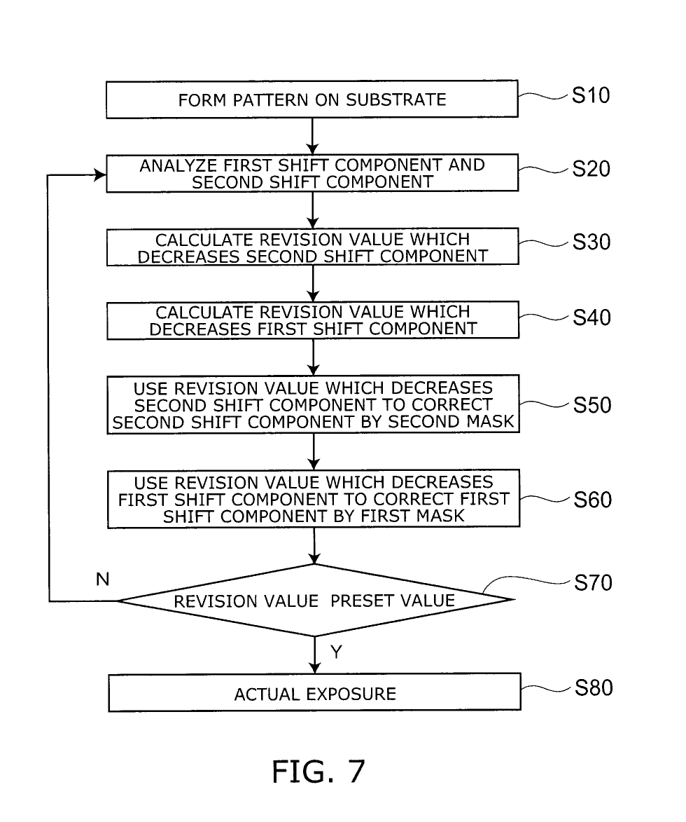

FIG. 7 is a flow chart showing an exposure method according to the embodiment.

The exposure method shown in FIG. 7 uses the exposure system 1.

First, a pattern is formed on the substrate 11 by irradiating the substrate with the light 70 through the first mask 20 (step S10). The exposure here serves as preliminary exposure (first exposure).

Next, the dimension and the misalignment of the pattern formed on the substrate 11 are measured by a dimension measurement system and misalignment measurement equipment that are not shown, followed by data analysis. These pieces of data are used to analyze a dimensional variation component (a second shift component) and a misalignment component (a first shift component) (step S20). That is, the data for correction is measured before performing the correction.

Among the aforementioned shift components, the first shift component based on the nonlinear component and the second shift component based on the light transmittance are analyzed automatically. The first shift component and the second shift component themselves are the values to be corrected. The first shift component and the second shift component are obtained by acquiring the data beforehand by the dimension measurement system and the misalignment measurement equipment that are not shown and analyzing the data in a device such as a computer. The relationship between the first shift component and the misalignment as well as the relationship between the second shift component and the light transmittance are obtained beforehand by an experiment or a simulation, and the resultant data is stored in the device such as the computer.

A revision value for decreasing the dimensional variation component (the second shift component) is now calculated (step S30).

Then, a revision value for decreasing the misalignment component (the first shift component) is calculated (step S40).

Subsequently, the revision value for decreasing the second shift component is used to correct the second shift component by the second mask 30 (step S50), where the second shift component decreases by adjusting the light transmittance of the second region 35 in the second mask 30 by forming the plurality of laser-irradiated marks 30a. That is, a second correction which decreases the second shift component is performed by forming the plurality of laser-irradiated marks 30a in the second region 35 of the second mask 30.

Then, the revision value for decreasing the first shift component is used to correct the first shift component by the first mask 20 (step S60), where a first correction which decreases the first shift component is performed by forming the plurality of laser-irradiated marks 20a in the first mask 20. That is, the misalignment of the nonlinear component based on the first mask decreases by forming the plurality of laser-irradiated marks 20a in the first mask 20.

Moreover, the relationship between the plurality of laser-irradiated marks 30a and the light transmittance correction as well as the relationship between the plurality of laser-irradiated marks 20a and the misalignment correction are obtained beforehand by an experiment or a simulation, so that the resultant data is stored in a device such as a computer.

Next, the exposure is performed to check and determine whether or not there is a problem in each of the revision values where, for example, it is determined whether or not the revision value is within a preset value (step S70). The adjustment is performed again when the revision value is outside the preset value. The exposure is actually performed when the revision value is within the preset value and has no problem (step S80). The exposure here serves as actual exposure (second exposure) against the preliminary exposure.

The second mask 30 in the embodiment is used to control the amount of light energy supplied to the first mask 20. Specifically, the laser-irradiated mark 30a is formed in the second mask 30 so that the light transmittance is partially controlled in the second mask 30. The light 70 with the corrected light transmittance is then supplied to the first mask 20. The misalignment of the nonlinear component by a mask is suppressed in the first mask 20. Specifically, the misalignment of the local nonlinear component is corrected by forming the laser-irradiated mark 20a in the light transparent substrate 22.

According to such method, the dimensional variation within a shot and the misalignment of the nonlinear component by a mask can be corrected in the respective masks. As a result, the correction of the dimensional variation within a shot and the correction of the misalignment of the nonlinear component by a mask do not interfere with each other. A desired pattern can therefore be formed on the substrate 11 with high precision each time the pattern formed on the substrate 11 becomes finer.

Moreover, the laser-irradiated mark is formed by an external laser irradiating module. The number, size, pitch, distribution and the like of the laser-irradiated mark to be formed in each of the first mask 20 and the second mask 30 are obtained by acquiring data beforehand by measurement equipment which measures data for analysis and analyzing the data in a device such as a computer. A desired laser-irradiated mark is formed in each of the first mask 20 and the second mask 30 on the basis of the calculation.

The number, size, pitch, distribution and the like of the laser-irradiated mark to be formed in each of the first mask 20 and the second mask 30 are obtained beforehand by experiment data or a simulation, for example. The laser-irradiated mark may be thereafter formed by the laser irradiating module from outside (not shown) the exposure system 1.

The same effect can be obtained by switching the order between step S30 and step S40. Moreover, the same effect can be obtained by switching the order between step S50 and step S60.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

The term “on” in “a portion A is provided on a portion B” refers to the case where the portion A is provided on the portion B such that the portion A is in contact with the portion B and the case where the portion A is provided above the portion B such that the portion A is not in contact with the portion B.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An exposure system comprising:
a supporting stage supporting a substrate;
a plurality of masks provided on an upper side of the supporting stage; and
a light source being capable of irradiating the substrate with light through the plurality of masks,
the plurality of masks including:
a first mask, and a light shielding film being patterned in the first mask; and
a second mask provided on an upper side or a lower side of the first mask, the second mask including a second region facing a first region of the first mask, the light shielding film not being present in the first region, and a light shielding film not being patterned in the second region or the light shielding film being patterned in at least a part of the second region, and
a plurality of laser-irradiated marks being provided in at least the second region of the second mask.

2. The system according to claim 1, wherein the second mask can be scanned on an upper side of the substrate in synchronization with the first mask.

3. The system according to claim 1, wherein a plurality of other laser-irradiated marks is provided outside the second region in the second mask.

4. The system according to claim 1, wherein a plurality of laser-irradiated marks is provided in the first mask, and the plurality of laser-irradiated marks in the first mask are different from the plurality of laser-irradiated marks in the second mask.

5. An exposure method using an exposure system,
the exposure system including:
a supporting stage supporting a substrate;
a plurality of masks provided on an upper side of the supporting stage; and
a light source being capable of irradiating the substrate with light through the plurality of masks,
the plurality of masks including:
a first mask, and a light shielding film being patterned in the first mask; and
a second mask provided on an upper side or a lower side of the first mask, the second mask including a second region facing a first region of the first mask, the light shielding film not being present in the first region, and a light shielding film not being patterned in the second region or the light shielding film being patterned in at least a part of the second region, and
a plurality of laser-irradiated marks being provided in at least the second region of the second mask, and
the method comprising:
(a) forming a pattern on a substrate by irradiating the substrate with light through a first mask;
(b) analyzing a first shift component based on a nonlinear component and a second shift component based on light transmittance from a shape of the pattern;
(c) calculating a revision value decreasing the second shift component;
(d) calculating a revision value decreasing the first shift component;
(e) correcting the second shift component by a second mask, using the revision value decreasing the second shift component; and
(f) correcting the first shift component by the first mask, using the revision value decreasing the first shift component.

6. The method according to claim 5 wherein, in the (f), misalignment of a nonlinear component based on the first mask is decreased by forming a plurality of first laser-irradiated marks in the first mask, and the plurality of first laser-irradiated marks can perform correction alignment.

7. The method according to claim 5 wherein, in the (e), transmittance of the light in the second mask is adjusted by forming a plurality of second laser-irradiated marks in the second mask, and the plurality of second laser-irradiated marks can perform correction illuminance.

8. The method according to claim 5, wherein the (d) is performed after the (c), or the (c) is performed after the (d).

9. The method according to claim 5, wherein the (f) is performed after the (e), or the (e) is performed after the (f).

10. The method according to claim 5, wherein a wavelength of the light is 100 nm to 400 nm.
